(19) United States
(12) Patent Application Publication
(10) Pub. No.: US 2025/0380455 A1
(43) Pub. Date: Dec. 11, 2025

(54) STACKED FIELD-EFFECT TRANSISTORS WITH ASYMMETRIC SOURCE/DRAIN REGIONS

(71) Applicant: INTERNATIONAL BUSINESS MACHINES CORPORATION, ARMONK, NY (US)

(72) Inventors: Debarghya Sarkar, Latham, NY (US); Jingyun Zhang, Albany, NY (US); Utkarsh Bajpai, Delmar, NY (US); Prabudhya Roy Chowdhury, Albany, NY (US); Teresa J. Wu, Rexford, NY (US); Abir Shadman, Albany, NY (US); Domingo Ferrer, Clifton Park, NY (US)

(21) Appl. No.: 18/737,998

(22) Filed: Jun. 8, 2024

(51) Int. Cl. H01L 29/417; H01L 21/822; H01L 21/8234; H01L 27/06; H01L 27/088; H01L 29/06; H01L 29/08; H01L 29/423; H01L 29/66; H01L 29/775; H01L 29/786

(52) U.S. Cl. CPC H10D 30/6729; H10D 30/014; H10D 30/43; H10D 30/6735; H10D 30/6757; H10D 62/121; H10D 62/151; H10D 84/013; H10D 84/038; H10D 84/83; H10D 88/00; H10D 88/01

(57) ABSTRACT

A semiconductor device includes a top source/drain region, a bottom source/drain region, and a conductive layer over a top surface and upper half of sidewalls of the bottom source/drain region. A length of the bottom source/drain region is larger than a length of the top source/drain region.

### BACKGROUND

### Technical Field

The present disclosure generally relates to transistors, and more particularly, to stacked field-effect transistor with asymmetric source/drain region structure, and methods of creation thereof.

### Description of the Related Art

Contact formation in a transistor is an aspect of semiconductor device fabrication that impacts the overall performance of the transistor. Contact resistance to the flow of electricity between the metal contacts and the semiconductor material within a transistor can impact the speed of operation and power consumption in electronic devices. Achieving contact formation with low contact resistance in transistors involves a combination of materials science, surface science, and precision fabrication techniques. Each step, from material selection and surface preparation to deposition and patterning, impacts the performance and reliability of the final semiconductor device.

### SUMMARY

According to an embodiment, a semiconductor device includes a top source/drain region, a bottom source/drain region, and a conductive layer over a top surface and upper half of sidewalls of the bottom source/drain region. A length of the bottom source/drain region is larger than a length of the top source/drain region.

In one embodiment, the conductive layer is a metal silicide layer.

In one embodiment, the semiconductor device includes a top contact connecting the top source/drain region to a back end of line (BEOL) through a first via and a metal line, and a bottom contact connecting the bottom source/drain region to the BEOL through the conductive layer, a second via, and the metal line.

In one embodiment, the bottom contact is isolated from the top source/drain region and the top contact by a dielectric layer.

In one embodiment, the semiconductor device includes a top transistor and a bottom transistor. The top transistor includes the top source/drain region, and the bottom transistor includes the bottom source/drain region.

In one embodiment, a length of the top transistor is equal to a length of the bottom transistor.

In one embodiment, the conductive layer is extended through the length of the bottom transistor.

In one embodiment, a resistivity of the conductive layer is less than 3e-9 ohm·cm².

In one embodiment, the conductive layer further covers the bottom half of sidewalls of the bottom source/drain region.

In one embodiment, the conductive layer conformally covers the top surface and the top half of sidewalls of the bottom source/drain region.

According to an embodiment, a method for forming a semiconductor device is disclosed. A top source/drain region, a bottom source/drain region, and a conductive layer over a top surface and upper half of sidewalls of the bottom source/drain region are formed. A length of the bottom source/drain region is larger than a length of the bottom source/drain region.

In one embodiment, conductive layer is a metal silicide layer.

In one embodiment, a top contact is formed which connects the top source/drain region to a back end of line (BEOL) through a first via and a metal line. A bottom contact is formed which connects the bottom source/drain region to the BEOL through the conductive layer, a second via and the metal line.

In one embodiment, the bottom contact is isolated from the top source/drain region and the top contact by a dielectric layer.

In one embodiment, a top transistor and a bottom transistor are formed. The top transistor includes the top source/drain region, and the bottom transistor includes the bottom source/drain region.

In one embodiment, the conductive layer is extended through a length of the bottom transistor.

In one embodiment, a bottom half of the sidewalls of the bottom source/drain region are covered by the conductive layer.

In one embodiment, the top surface and the top half of sidewalls of the bottom source/drain region are conformally covered by the conductive layer.

According to an embodiment, a semiconductor device includes a first source/drain region, a conductive layer over a top surface and upper half of sidewalls of the first source/drain region, and a first contact connecting the first source/drain region to the BEOL through a conductive layer, a via and a metal line.

In one embodiment, the semiconductor device includes a second source/drain region, wherein a length of the first source/drain region is larger than a length of the second source/drain region.

These and other features will become apparent from the following detailed description of illustrative embodiments thereof, which is to be read in connection with the accompanying drawings.

### BRIEF DESCRIPTION OF THE DRAWINGS

The drawings are of illustrative embodiments. They do not illustrate all embodiments. Other embodiments may be used in addition or instead. Details that may be apparent or unnecessary may be omitted to save space or for more effective illustration. Some embodiments may be practiced with additional components or steps and/or without all the components or steps that are illustrated. When the same numeral appears in different drawings, it refers to the same or like components or steps.

FIGS. 1A-1B illustrate conventional semiconductor devices.

FIG. 2 illustrates a side-view of a semiconductor device, in accordance with some embodiments.

FIG. 3 illustrates a side-view of a semiconductor device with conformal conductive layer, in accordance with some embodiments.

FIG. 4 illustrates a side-view of a semiconductor device with wrap-around conductive layer, in accordance with some embodiments.

FIGS. 5A-5B illustrate side-views of a semiconductor device after the recession of the nanosheets, in accordance with some embodiments.

FIG. 5C illustrates a top view of the semiconductor device, in accordance with some embodiments.

FIGS. 6A-6B illustrate side-views of a semiconductor device after the formation of the bottom source/drain region, in accordance with some embodiments.

FIGS. 7A-7B illustrate side-views of a semiconductor device after the recession of the bottom source/drain region, and the inner spacer is formed, in accordance with some embodiments.

FIGS. 8A-8B illustrate side-views of a semiconductor device after the deposition of the conductive layer, in accordance with some embodiments.

FIGS. 9A-9B illustrate side-views of a semiconductor device after the crystallization of the conductive layer, in accordance with some embodiments.

FIGS. 10A-10B illustrate side-views of a semiconductor device after the removal of the liner layer, in accordance with some embodiments.

FIGS. 11A-11B illustrate side-views of a semiconductor device after the formation of the top source/drain region, in accordance with some embodiments.

FIGS. 12A-12B illustrate side-views of a semiconductor device after the formation of additional interlayer dielectric, in accordance with some embodiments.

FIGS. 13A-13B illustrate side-views of a semiconductor device after the middle of line processing, in accordance with some embodiments.

FIGS. 14A-14B illustrate side-views of a semiconductor device after the formation of the interconnects, in accordance with some embodiments.

FIGS. 15A-15B illustrate a contact resistivity estimation for a conventional source/drain region and a semiconductor device, in accordance with some embodiments.

FIG. 16 illustrates a contact resistivity estimation based on a thickness of the conductive layer, in accordance with some embodiments.

FIG. 17 illustrates block diagrams of a method for forming the semiconductor device, in accordance with some embodiments.

### DETAILED DESCRIPTION

### Overview

In the following detailed description, numerous specific details are set forth by way of examples to provide a thorough understanding of the relevant teachings. However, it should be apparent that the present teachings may be practiced without such details. In other instances, well-known methods, procedures, components, and/or circuitry have been described at a relatively high-level, without detail, to avoid unnecessarily obscuring aspects of the present teachings.

In one aspect, spatially related terminology such as “front,” “back,” “top,” “bottom,” “beneath,” “below,” “lower,” above,” “upper,” “side,” “left,” “right,” and the like, is used with reference to the orientation of the Figures being described. Since components of embodiments of the disclosure can be positioned in a number of different orientations, the directional terminology is used for purposes of illustration and is in no way limiting. Thus, it will be understood that the spatially relative terminology is intended to encompass different orientations of the device in use or operation in addition to the orientation depicted in the figures. For example, if the device in the figures is turned over, elements described as “below” or “beneath” other elements or features would then be oriented “above” the other elements or features. Thus, for example, the term “below” can encompass both an orientation that is above, as well as below. The device may be otherwise oriented (rotated 90 degrees or viewed or referenced at other orientations) and the spatially relative descriptors used herein should be interpreted accordingly.

As used herein, the terms “lateral” and “horizontal” describe an orientation parallel to a first surface of a chip.

As used herein, the term “vertical” describes an orientation that is arranged perpendicular to the first surface of a chip, chip carrier, or semiconductor body.

As used herein, the terms “coupled” and/or “electrically coupled” are not meant to mean that the elements must be directly coupled together-intervening elements may be provided between the “coupled” or “electrically coupled” elements. In contrast, if an element is referred to as being “directly connected” or “directly coupled” to another element, there are no intervening elements present. The term “electrically connected” refers to a low-ohmic electric connection between the elements electrically connected together.

Although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

Example embodiments are described herein with reference to cross-sectional illustrations that are schematic illustrations of idealized or simplified embodiments (and intermediate structures). As such, variations from the shapes of the illustrations as a result, for example, of manufacturing techniques and/or tolerances, may be expected. Thus, the regions illustrated in the figures are schematic in nature and their shapes do not necessarily illustrate the actual shape of a region of a device and do not limit the scope.

It is to be understood that other embodiments may be used and structural or logical changes may be made without departing from the spirit and scope defined by the claims. The description of the embodiments is not limiting. In particular, elements of the embodiments described hereinafter may be combined with elements of different embodiments.

The concepts herein relate to stacked field-effect transistor (FET), which are fundamental electronic devices that have revolutionized the field of electronics and how various elements of the transistors are electrically connected. The stacked FET is a type of transistor architecture that offers improved functionality and benefits in integrated circuit (IC) design. The stacked FET involves stacking multiple FETs on top of each other, allowing for enhanced performance and increased integration density.

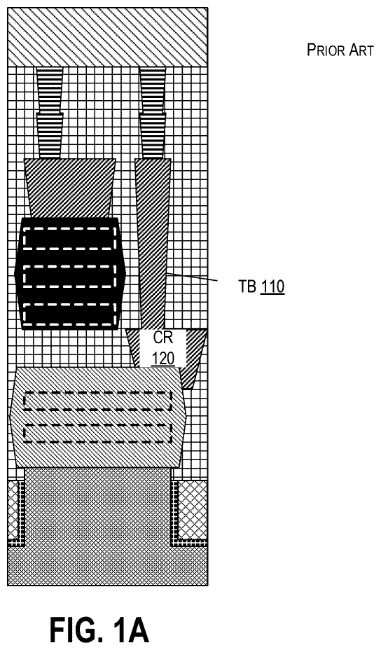

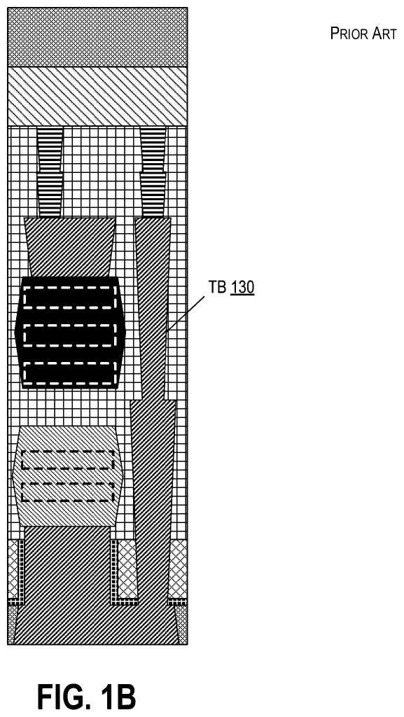

As semiconductor devices are scaled down, the challenges associated with maintaining low contact resistance while managing the physical dimensions of the device components become more significant. In traditional stacked FET architectures, particularly those utilizing L-shaped structures. L refers to the shape of the stacked FET with shorter sheet width on the top and longer sheet width on the bottom, such as the semiconductor device shown in FIG. 1A, the need to increase the cell height to accommodate the structure results in contacts that require high aspect ratio trenches. These high aspect ratio trenches are prone to lateral overlay errors during the lithography process, which can reduce the contact area available for the formation of metal-semiconductor interfaces, subsequently increasing the contact resistance. Additionally, such structures often involve complex fabrication processes that can introduce variability and reduce yield.

Alternatively, I-shaped structures, I refers to shape of the stacked FET with same sheet width on the top and bottom and aligned vertically with respect to each other, the long vertical bottom contact TB 130, such as the semiconductor device shown in FIG. 1B, have been utilized to address some of these issues but they also come with their own set of challenges. These structures typically involve the formation of contacts from the backside of the wafer, involving high aspect ratio structures that are difficult to fill uniformly and can complicate the integration flow. Furthermore, while the channel inversion length can remain largely constant, the middle of line (MOL) processes results in very narrow contact lengths in the cross-gate direction, exacerbating the problem of increased contact resistance due to reduced metal-semiconductor contact area.

In view of the above considerations, disclosed is a semiconductor device with asymmetric source/drain regions. The disclosed semiconductor device can maintain a high metal-semiconductor contact area, thereby ensuring low contact resistance even as the dimensions of the MOL metal conduit are reduced. This is achieved by employing a configuration that optimizes the geometry and spatial arrangement of the contact areas, facilitating enhanced conductivity and reducing the incidence of electrical resistance bottlenecks. The disclosed semiconductor device structure is designed to be compatible with existing integration flows, thereby simplifying the manufacturing process and improving the overall manufacturability of the semiconductor devices.

The disclosed semiconductor device improves the technology of semiconductor device fabrication by providing a solution that not only addresses the fundamental issue of contact resistance in scaled devices, but also enhances the reliability and performance of the devices. The structural design introduced by the semiconductor device represents a pivotal improvement over existing technologies by ensuring that high contact efficiency is maintained without compromising the scalability and functionality of the semiconductor devices.

Accordingly, the teachings herein provide methods and systems of semiconductor device formation with asymmetric source/drain regions. The techniques described herein may be implemented in a number of ways. Example implementations are provided below with reference to the following figures.

### Example Semiconductor Device With Asymmetric Source/Drain Regions Structure

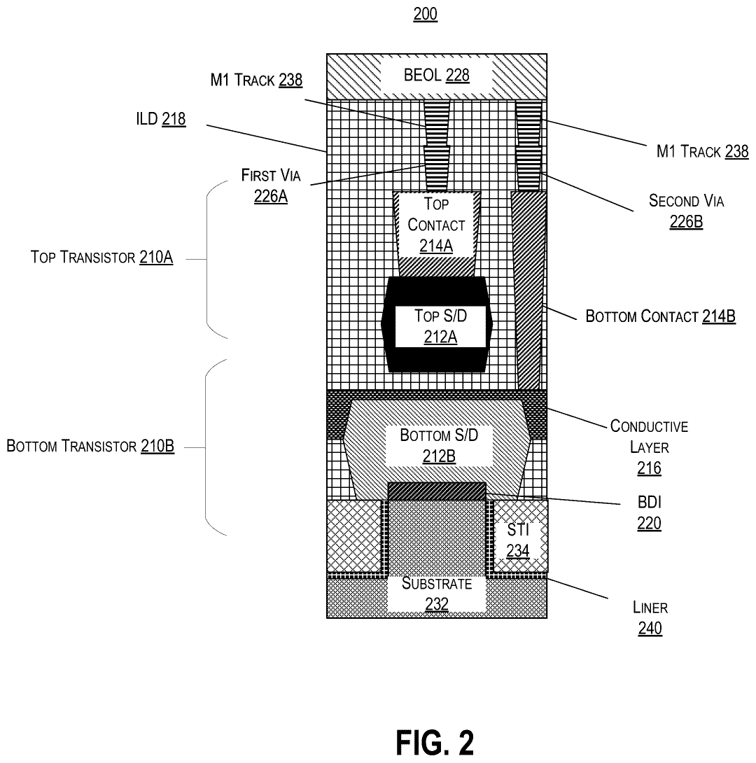

Reference now is made to FIG. 2, which is a simplified cross-section view of a source/drain region side of a semiconductor device 200, consistent with an illustrative embodiment. In various embodiments, the semiconductor device 200 is a stacked field-effect transistor (FET) that leverages the vertical dimension of the semiconductor device 200 to increase the number of active devices within a given area. This way, instead of relying solely on lateral scaling, where semiconductor devices are shrunk in size on the semiconductor substrate, stacking FETs vertically can enable the incorporation of multiple layers of semiconductor devices. This arrangement enables more complex circuitry and advanced functionality. In various embodiments, the semiconductor device 200 can include multiple transistors connected in series, with the source region of one transistor connected to the drain of the previous transistor. This configuration allows for sequential signal propagation and enables advanced logic operations. By stacking the transistors, the overall gain of the semiconductor device 200 can be increased, leading to improved performance characteristics, such as higher speed and better noise immunity. In some embodiments, the stacked FET structure of the semiconductor device 200 can provide improved performance compared to traditional single-transistor design. By increasing the number of active devices in a given area, the semiconductor device 200 can achieve higher drive currents, resulting in faster switching speeds and improved signal propagation, which in turn enables the design of high-performance digital circuits, such as microprocessors and high-speed communication interfaces.

In several embodiments, the stacked FET structure of the semiconductor device 200 can enhance power efficiency by reducing the overall resistance of the semiconductor device 200. By stacking transistors in series, the effective resistance of the semiconductor device 200 can be increased, resulting in lower power consumption, which can be beneficial in portable devices and energy-efficient applications where power efficiency is a critical factor. In additional embodiments, the stacked FET structure of the semiconductor device 200 can enable higher integration densities by utilizing the vertical dimension of the semiconductor device 200. In such embodiments, instead of relying solely on lateral scaling, which has its limits, stacking FETs on the semiconductor device 200 allows for increased transistor count within a given chip area. This increased transistor count enables the integration of more complex circuits, larger memory arrays, and other functional blocks, enhancing the capabilities of the semiconductor device 200.

In an embodiment, the stacked FET structure of the semiconductor device 200 can offer improved noise immunity due to higher gain. The sequential arrangement of stacked FETs in series amplifies the signal as the signal propagates through the stacked structure of the semiconductor device 200, making it less susceptible to noise and improving the overall signal-to-noise ratio. This amplification can be advantageous in high-noise environments or in applications where signal integrity is critical. In some embodiments, the stacked FET structure of the semiconductor device 200 can provide increased flexibility in circuit design. The availability of stacked FETs, i.e., multiple transistor layers, allows for the implementation of more complex logic functions, specialized circuit topologies, and improved design optimization. Such a complex implementation can enable the realization of custom semiconductor device designs tailored to specific requirements or applications.

The semiconductor device 200 leverages asymmetric epitaxial growth with a lateral overburden on one side to manage cell height effectively, aligning with the dimensions typically seen in I-shaped FETs (as shown in FIG. 1B) while facilitating signal routing to the backside of the bottom source/drain region. In this approach, one side of the bottom source/drain region undergoes a controlled overburden, which not only optimizes the spatial dimensions of the transistor but also simplifies the integration of backside signal routing without compromising the structural integrity of the device. This configuration allows the cell height to be maintained at levels comparable to or better than those achieved with conventional I-shaped FETs, thus supporting more compact and efficient device architectures. Further enhancing the semiconductor device's performance, a conductive layer is applied across a large area of the epi surface. This conductive layer reduces the contact resistance by providing a robust, low-resistance interface between the source/drain region and the metal contacts.

The disclosed semiconductor device 200 can include a top transistor 210A and a bottom transistor 210B. The top transistor 210A can include a top source/drain region 212A, and the bottom transistor 210B can include a bottom source/drain regions 212B. The semiconductor device 200 can further include a top contact 214A, a bottom contact 214B, a conductive layer 216, an interlayer dielectric, ILD 218, a bottom dielectric isolation, BDI 220, a first via 226A, a second via 226B, a back end of line, BEOL 228, a substrate 232, shallow trench isolation, STI 234, a metal line, M1 track 238, and a liner 240.

Generally, the top source/drain region 212A and the bottom source/drain region 212B are two salient components that play relevant roles in the semiconductor device's operation. In various embodiments, the top source/drain region 212A and the bottom source/drain region 212B are regions within the semiconductor material, e.g., the semiconductor device 200, where the current flows in and out of the semiconductor device 200. The source region is the region through which the majority of charge carriers (e.g., electrons or holes) enter the channel of the semiconductor device and is responsible for providing the current that flows through the semiconductor device. The source region is typically doped to have an excess of charge carriers, creating a region with high carrier concentration. This abundance of carriers allows for the efficient injection of electrons or holes into the channel when a voltage is applied. The drain region, on the other hand, is the region where the majority of charge carriers exit the channel. The drain region receives the current from the channel and carries the charge away from the transistor. Similar to the source, the drain region is also doped to have a high carrier concentration. The doping profile in the drain region ensures that carriers can easily flow out of the channel and into the drain region.

In some embodiments, the top source/drain region 212A is located on the top transistor 210A, and the bottom source/drain region 212B is located on the bottom transistor 210B. The top transistor 210A can be stacked on top of the bottom transistor 210B to form the semiconductor device 200. The channel width of the top transistor 210A can be equal to the channel width length of the bottom transistor 210B.

In some embodiments, the length of the bottom source/drain region 212B is larger than the length of the top source/drain region 212A. In other words, the source/drain regions of the semiconductor device 200 are asymmetric, which can enable formation of the bottom contact 214B extended vertically from the bottom contact 214B through the second via 226B and the M1 track 238 to the BEOL 228.

The top contact 214A, located over the top source/drain region 212A, establishes a connection between the top source/drain region 212A and the BEOL 228 through the first via 226A and the M1 track 238. The top contact 214A ensures efficient electrical routing and connectivity within the semiconductor device 200. The fabrication of the top contact 214A can involve lithography and etching processes to define the contact area. The top contact 214A can be made using conductive materials such as copper (Cu) or tungsten (W).

The bottom contact 214B, located over the bottom source/drain region 212B, establishes a connection between the bottom source/drain region 212B and the BEOL 228 through the conductive layer 216. The bottom contact 214B ensures efficient electrical routing and connectivity within the semiconductor device 200. The fabrication of the bottom contact 214B can involve lithography and etching processes to define the contact area. The bottom contact 214B can be made using conductive materials such as copper (Cu) or tungsten (W). In some embodiments, the bottom contact 214B is isolated from direct contact with the top source/drain region 212A and the top contact 214A by the ILD 218.

The conductive layer 216 can cover the top surface and the upper half of sidewalls of the bottom source/drain region 212B. In some embodiments, the conductive layer 216, which can be made of a metal silicide, can be extended horizontally along the bottom transistor 210B in such a way to fill the entire length of active region of the bottom transistor 210B. In various embodiments, the resistivity of the conductive layer-bottom source/drain region is equal to or less than 3e-9 ohm·cm².

The ILD 218 can be a layer of insulating material to electrically isolate and provide mechanical support between different layers of conducting and active components. The ILD 218 can enable efficient signal transmission, reduce crosstalk, and ensure the proper functioning of the semiconductor device 200. In an embodiment, the ILD 218 can electrically isolate adjacent conducting layers or active components in the semiconductor device 200. By providing insulation between different layers, the ILD 218 can prevent electrical shorts, reduce (e.g., minimize) leakage current, and ensure that signals are directed only along the desired pathways. In some embodiments, the ILD 218 can help reduce parasitic capacitance between adjacent metal interconnects or active devices and provide mechanical support to the semiconductor device's structure.

The BDI 220 can electrically isolate individual components in the semiconductor device 200, and provide electrical isolation between the bottom FET and the substrate to prevent electrical leakage to the substrate.

The first via 226A establishes a vertical electrical connection between the top source/drain region 212A and the BEOL 228 through the top contact 214A. The first via 226A can facilitate efficient power delivery and signal transmission between the top source/drain region 212A and the BEOL 228. Fabrication of the first via 226A involves a series of processes, including lithography, etching, and deposition. The first via 226A can be formed using conductive materials such as copper (Cu) or tungsten (W). The presence of the first via 226A enables improved (e.g., optimal) electrical connectivity, contributing to improved device performance and reduced power losses.

In various embodiments, the first via 226A is connected to the BEOL 228 via the M1 track 238. The M1 track 238 can be recessed to form multiple separate M1 portions. In other words, each M1 portion can be electrically isolated from other M1 portions. In an embodiment, each M1 portion can be used to connect an element of the semiconductor device 200 to the BEOL 228.

The second via 226B connects the bottom source/drain region 212B to the BEOL 228. The second via 226B can establish a vertical electrical pathway between the bottom source/drain region 212B and the BEOL 228. The fabrication of the second via 226B involves lithography, etching, and deposition processes similar to those used for the first via. The second via 226B can be formed using conductive materials like copper (Cu) or tungsten (W). The presence of the second via 226B enables efficient electrical routing and connectivity, promoting enhanced signal transmission and overall device performance. The liner 240 can isolate the substrate 232 from direct contact with the STI 234. In some embodiments, the liner 240 can be made of a nitride.

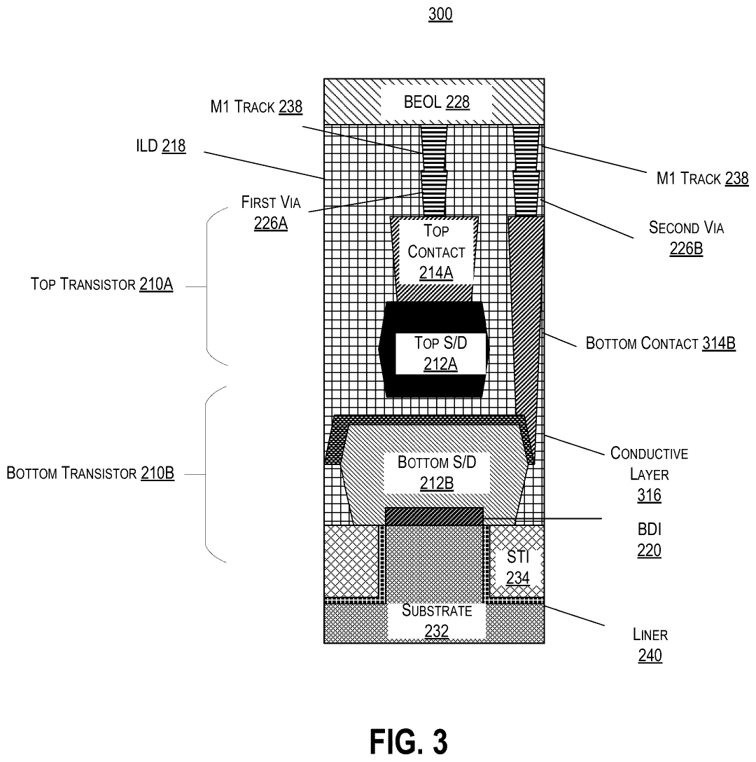

Reference now is made to FIG. 3, which is a simplified cross-section view of a semiconductor device 300 with conformal conductive layer, consistent with an illustrative embodiment. The semiconductor device 300 depicted in FIG. 3 can be similar to the semiconductor device 200 depicted in FIG. 2, with the conductive layer 316 conformally covering the top surface and the top half of the sidewalls of the bottom source/drain region 212B. As a result, the portions of the conductive layer 316 covering the top half of the sidewalls of the bottom source/drain region 212B are angled to conform to the sidewalls of the bottom source/drain region 212B. In other words, the conductive layer 216 is not conformal to the sidewall of the bottom S/D region. Further, the bottom contact 314B is extended vertically to cover the conformal portions of the conductive layer 316.

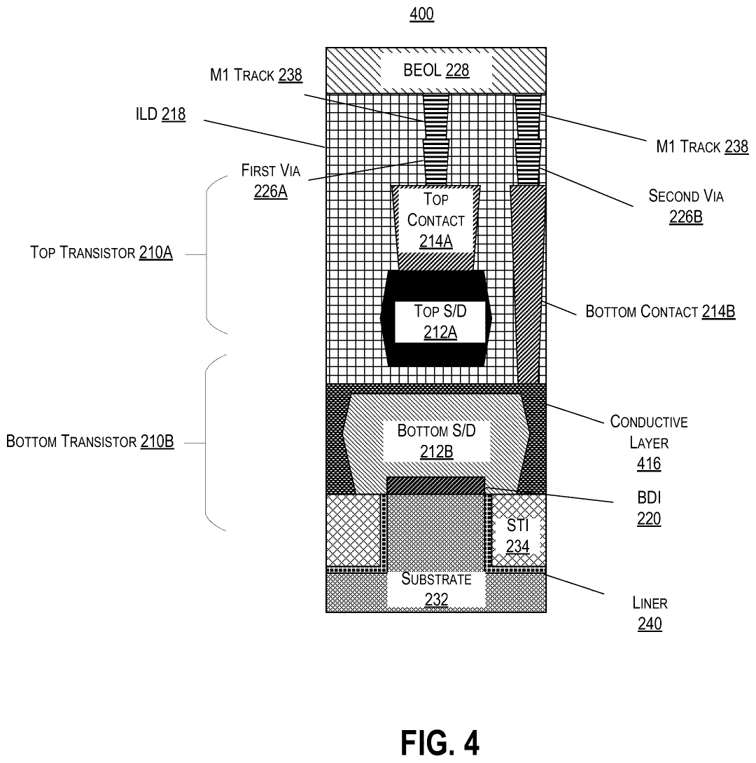

Reference now is made to FIG. 4, which is a simplified cross-section view of a semiconductor device 400 with wrap-around conductive layer, consistent with an illustrative embodiment. The semiconductor device 400 depicted in FIG. 4 can be similar to the semiconductor device 200 depicted in FIG. 2, with the conductive layer 416 wrapping-around the bottom source/drain region 212B, covering the top surface, the top half of the sidewalls, and the bottom half of the sidewalls of the bottom source/drain region 212B. As a result, the conductive layer 416 encapsulates the bottom source/drain region 212B except the bottom surface of the bottom source/drain region 212B.

### Example Processes for Semiconductor Device With Asymmetric Source/Drain Regions Structures

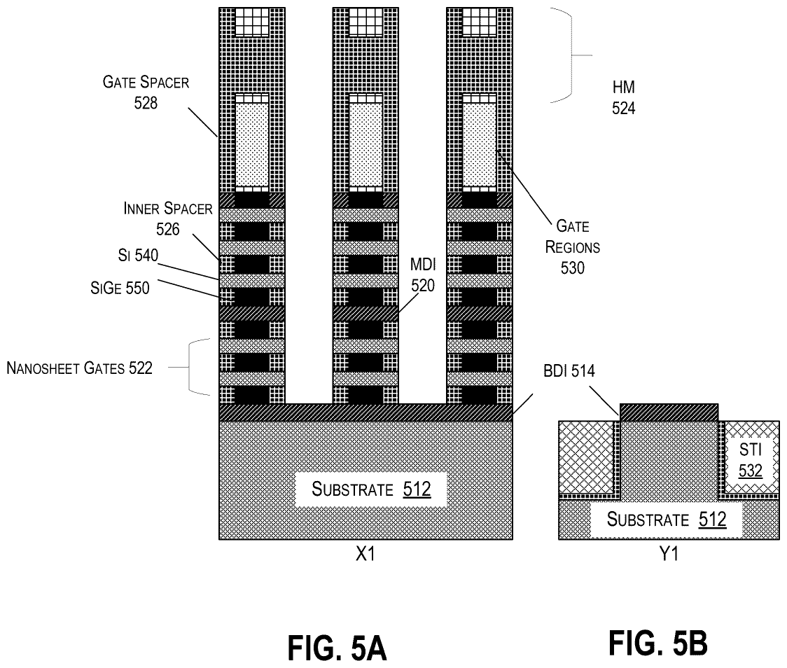

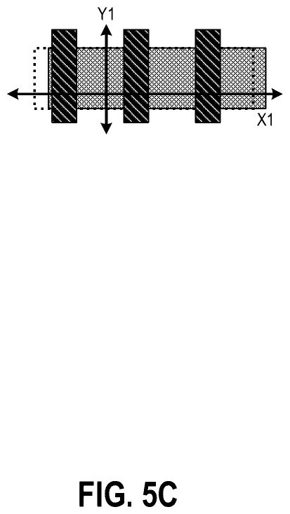

With the foregoing description of an example semiconductor device 200, it may be helpful to discuss an example process of manufacturing the same. To that end, FIGS. 5-15 illustrate various steps in the manufacture of a semiconductor device, consistent with illustrative embodiments. It should be noted, figures denoted by A and B illustrate acts of fabrication of the semiconductor device from a different point of view. FIG. 5C illustrates a top view of the semiconductor device depicted in FIGS. 5A-5B. It is also worth mentioning that the semiconductor depicted in FIG. 2 can be the same as the semiconductor depicted in FIGS. 5-15.

Referring to FIGS. 5A-5B now, a semiconductor device is illustrated after the recession of the nanosheets. Once the nanosheet recession is performed, the semiconductor can include a substrate 512, BDI 514, a middle dielectric isolation, MDI 520, nanosheet structures 522, gate hard mask, HM 524, inner spacer 526, an interlayer dielectric, gate spacers 528, dummy gate regions 530, and STI 532.

In the illustrative example depicted in FIGS. 5A-5B, the semiconductor device is depicted as being on silicon as the substrate 512, while it will be understood that other types as substrates may be used as well, including, without limitation, monocrystalline Si, silicon germanium (SiGe), III-V compound semiconductor, II-VI compound semiconductor, or semiconductor-on-insulator (SOI). Group III-V compound semiconductors, for example, include materials having at least one group III element and at least one group V element, such as one or more of aluminum gallium arsenide (AlGaAs), aluminum gallium nitride (AlGaN), aluminum arsenide (AlAs), aluminum indium arsenide (AlIAs), aluminum nitride (AlN), gallium antimonide (GaSb), gallium aluminum antimonide (GaAlSb), gallium arsenide (GaAs), gallium arsenide antimonide (GaAsSb), gallium nitride (GaN), indium antimonide (InSb), indium arsenide (InAs), indium gallium arsenide (InGaAs), indium gallium arsenide phosphide (InGaAsP), indium gallium nitride (InGaN), indium nitride (InN), indium phosphide (InP) and alloy combinations including at least one of the foregoing materials. The alloy combinations can include binary (two elements, e.g., gallium (III) arsenide (GaAs)), ternary (three elements, e.g., InGaAs), and quaternary (four elements, e.g., aluminum gallium indium phosphide (AlInGaP)) alloys.

In various embodiments, the substrates 512 may include any suitable material or combination of materials, such as doped or undoped silicon, glass, dielectrics, etc. For example, the substrate may include a silicon-on-insulator (SOI) structure, e.g., with a buried insulator layer, or a bulk material substrate, e.g., with appropriately doped regions, typically referred to as wells. In another embodiment, the substrate may be silicon with silicon oxide, nitride, or any other insulating film on top.

The MDI 520, similar to the BDI 514, can electrically isolate individual components in the semiconductor device, and provide electrical isolation between each of the FETs in the stacked FET. That is, the MDI 520 can ensure that the operation of one transistor does not interfere with the operation of the others. By using a dielectric layer, which is an insulating layer that does not conduct electricity, the MDI 520 effectively prevents electrical crosstalk between the transistors and allows each one to operate independently. Further, by electrically isolating each transistor from the other, the MDI 520 can reduce the potential for crosstalk, which is the unwanted transfer of signals between circuit elements, thereby improving the overall performance of the semiconductor device.

By isolating each transistor, MDI 520 helps to prevent the failure of one transistor from affecting the others. This can improve the overall reliability of the device. Additionally, the MDI 520 allows for more flexibility in device design, as it allows each transistor in the stack to be accessed and controlled independently. This can be beneficial in a variety of applications where specific transistors may need to be activated or deactivated based on certain conditions. In some embodiments, the MDI 520 can help decrease the parasitic capacitance associated with the transistor, which can lead to faster switching times and improved performance.

In some embodiments, the nanosheet structures 522 can be formed by alternating layers of Si 540 and SiGe 550, in which sidewalls of the layers of SiGe 550 are indented and covered by the inner spacer 526. The layers of SiGe 550 can subsequently be removed and replaced with gate region materials.

The gate spacers 528 can be thin insulating layers or materials placed on the sidewalls of the dummy gate regions 530. The gate spacers 528 can help control the effective channel length of the semiconductor device. In an embodiment, the gate spacers 528 can allow for control over the channel's conductive properties, including resistance and carrier mobility, which can contribute to improved performance of the semiconductor device.

In some embodiments, the gate spacers 528 can help prevent current leakage or short circuits between the dummy gate regions 530 and other parts of the semiconductor device. Such isolation can help maintain the integrity of the semiconductor device's electrical operation and prevent unintended current flow that could negatively impact the performance of the semiconductor device and reliability.

In further embodiments, the HM 524 can be utilized to modulate the overlapping capacitance between the dummy gate regions 530 and the other parts of the semiconductor device. Overlapping capacitance can affect the semiconductor device's electrical characteristics, such as threshold voltage and switching behavior. Thus, by adjusting the thickness and material properties of the HM 524, the overlapping capacitance can be optimized, which can allow for better control and modulation of the semiconductor device's behavior.

In several embodiments, the HM 524 can create a barrier that restricts the extension of the electric field into the channel region, reducing the impact of drain-induced barrier lowering and subthreshold leakage. This mitigation can improve the semiconductor device's performance, reduce power consumption, and enhance overall device reliability. In some embodiments, the HM 524 can be formed over the sidewalls of the dummy gate regions 530. The HM 524 can be formed by deposition techniques. Alternatively, the HM 524 can be formed by etching or selectively epitaxially growing the HM 524 over the sidewalls of the dummy gate regions 530. In various embodiments, the HM 524 can include SiGe.

In various embodiments, the gate region 530 serves as control elements that regulate the flow of current through the semiconductor device. The gate region 530 can be composed of a conductive material. The gate region 530 can control the flow of electric current between the source and drain regions. In some embodiments, by applying a voltage to the gate, the channel region's conductivity is modulated, allowing the semiconductor device to either allow or block the flow of current, which in turn enables the semiconductor device to act as electronic switches or amplifiers. The gate voltage can determine whether the semiconductor device is in an “on” or “off” state. When the gate voltage is below a certain threshold, the semiconductor device is in the “off” state, and the current flow between the source and drain is effectively blocked. On the other hand, when the gate voltage exceeds the threshold, the semiconductor device enters the “on” state, allowing current to flow through the channel region. In addition to acting as a switch, modulating the gate voltage can enable the gate region 530 to control the current flowing through the channel region, resulting in amplified output signals.

In an embodiment, the gate region 530 can enable the implementation of Boolean logic operations, such as AND, OR, and NOT, by controlling the flow of current based on the input voltages. Multiple semiconductor devices can be interconnected to form complex logic circuits, enabling the execution of various computational tasks in digital systems. In some embodiments, the gate region 530, along with other semiconductor device components, can facilitate the miniaturization and integration of electronic circuits. The ability to control the channel region's conductivity through the gate voltage allows for compact and highly efficient circuit designs.

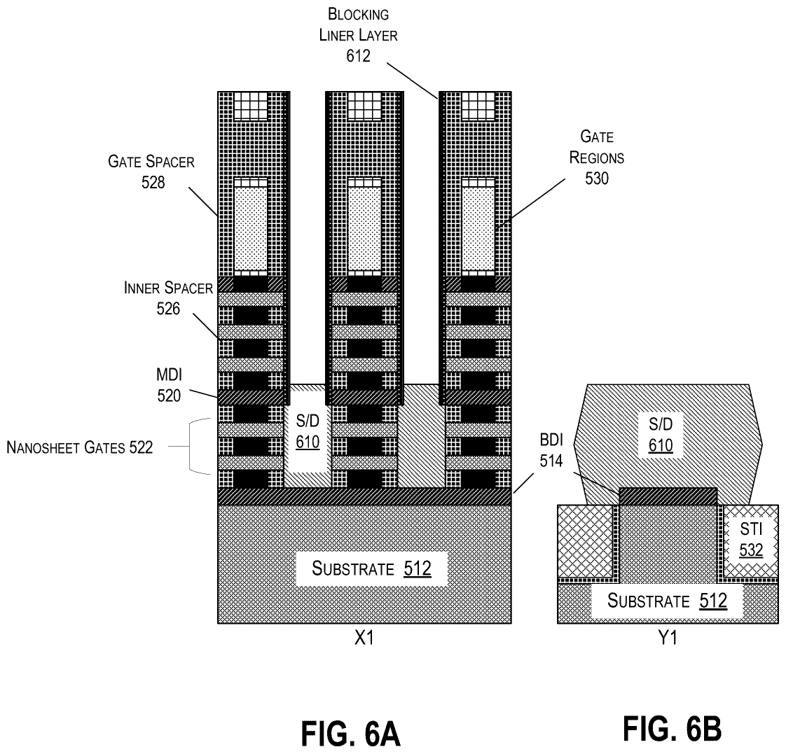

FIGS. 6A-6B illustrate side-views of a semiconductor device after the formation of the bottom source/drain region, in accordance with some embodiments. In an embodiment, the bottom source/drain region 610 is formed by epitaxial growth. The bottom source/drain region 610 can be grown with isotropic overburden. In some embodiments, a blocking liner layer 612 is formed over the sidewalls of the dummy gate structure above the bottom transistor.

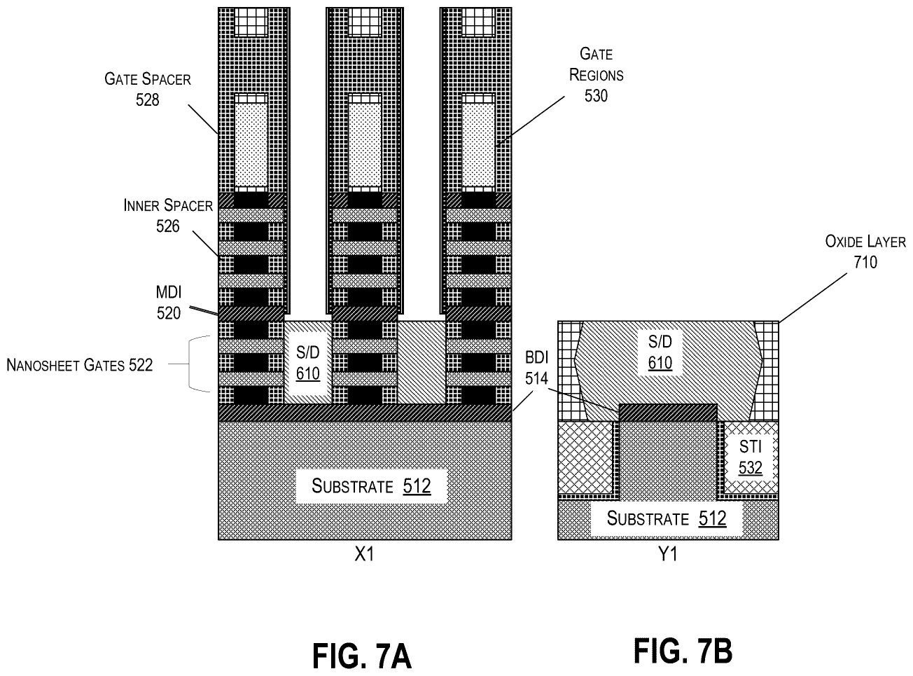

FIGS. 7A-7B illustrate side-views of a semiconductor device after the recession of bottom source/drain region, in accordance with some embodiments. In an embodiment, portion of the top surface of the bottom source/drain region 610 are removed. An oxide layer 710 can be formed to fill portions of the bottom transistor which are not covered by the bottom source/drain region 610.

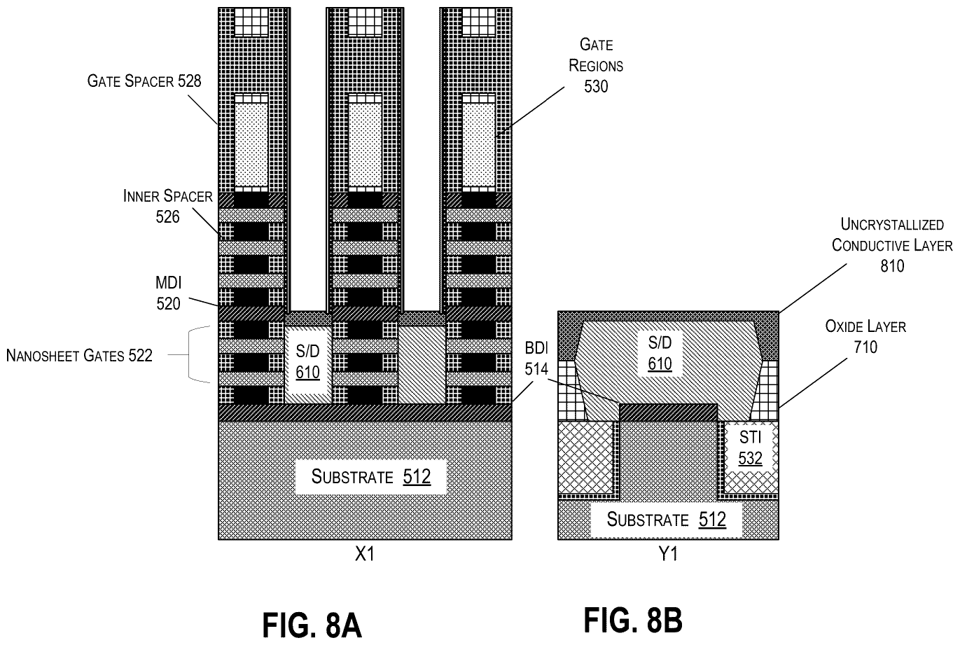

FIGS. 8A-8B illustrate side-views of a semiconductor device after the deposition of the conductive layer over the bottom source/drain region, in accordance with some embodiments. In an embodiment, the uncrystallized conductive layer 810, e.g., the metal plus amorphous silicon, is formed over the upper half of the sidewalls and the top surface of the bottom source/drain region 610.

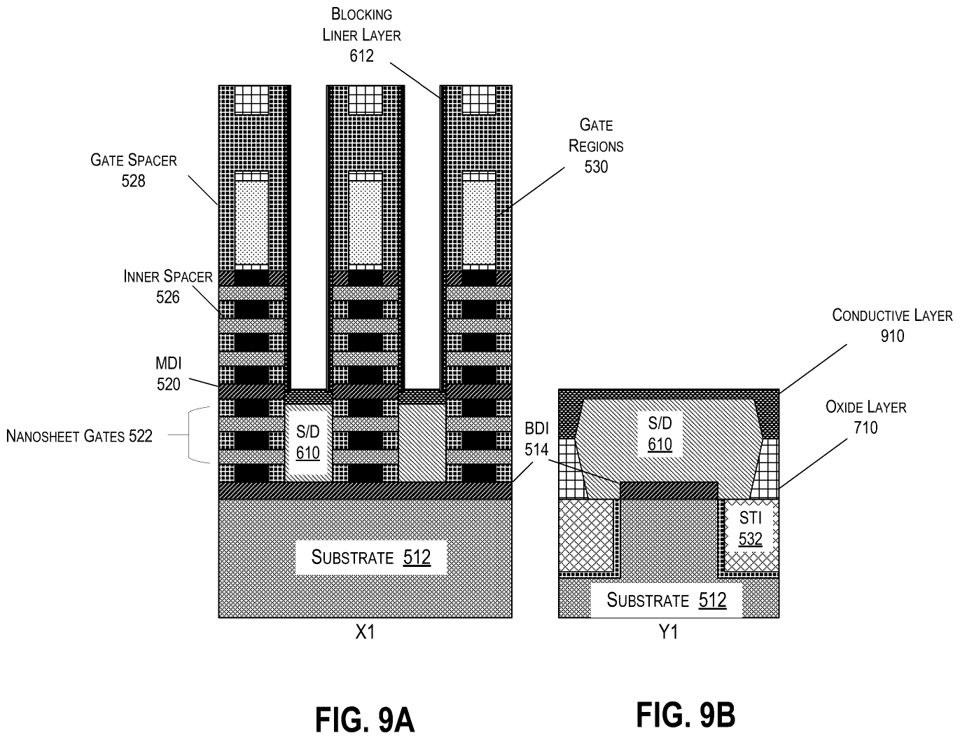

FIGS. 9A-9B illustrate side-views of a semiconductor device after the crystallization of the conductive layer, in accordance with some embodiments. In an embodiment, the uncrystallized conductive layer 810 is crystallized to form the conductive layer 910. An excess amount of uncrystallized conductive layer is removed. In some embodiments, the resistivity of the conductive layer/bottom source/drain region is less than 3e-9 Ohm·Cm²

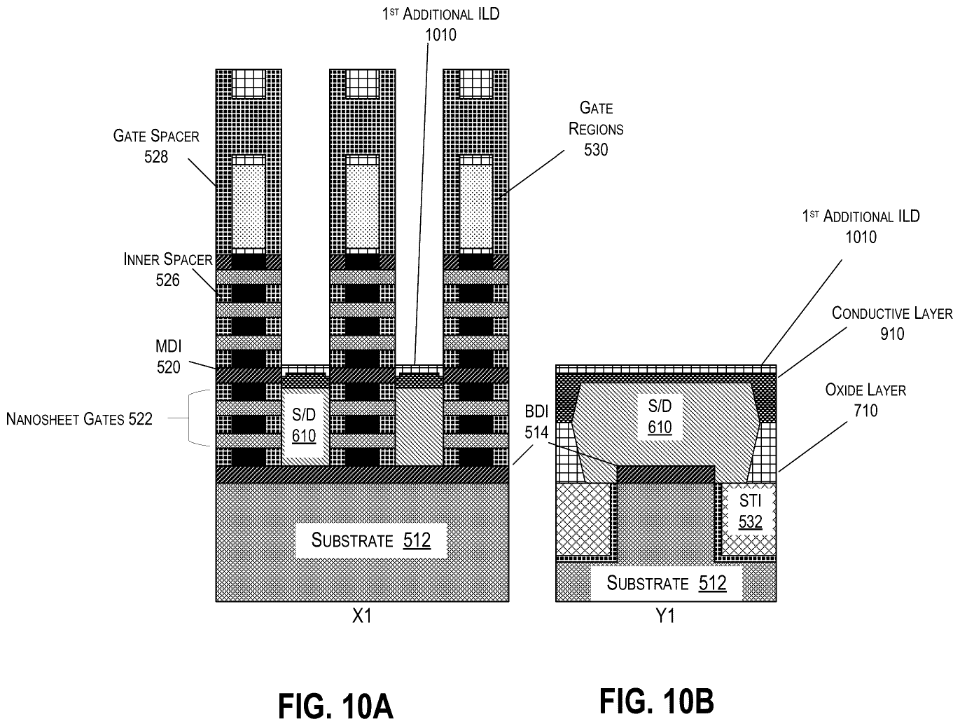

FIGS. 10A-10B illustrate side-views of a semiconductor device after the removal of the liner layer, in accordance with some embodiments. In an embodiment, the liner layer over the sidewalls of the nanosheets gates/gate regions stacks is removed. In some embodiments, a first additional layer of ILD 1010 can be formed over the top surface of the conductive layer 910. In some embodiments, a blanket dielectric deposition followed by chemical-mechanical-polishing (CMP) and a recess process can be performed to obtain the indicated structure.

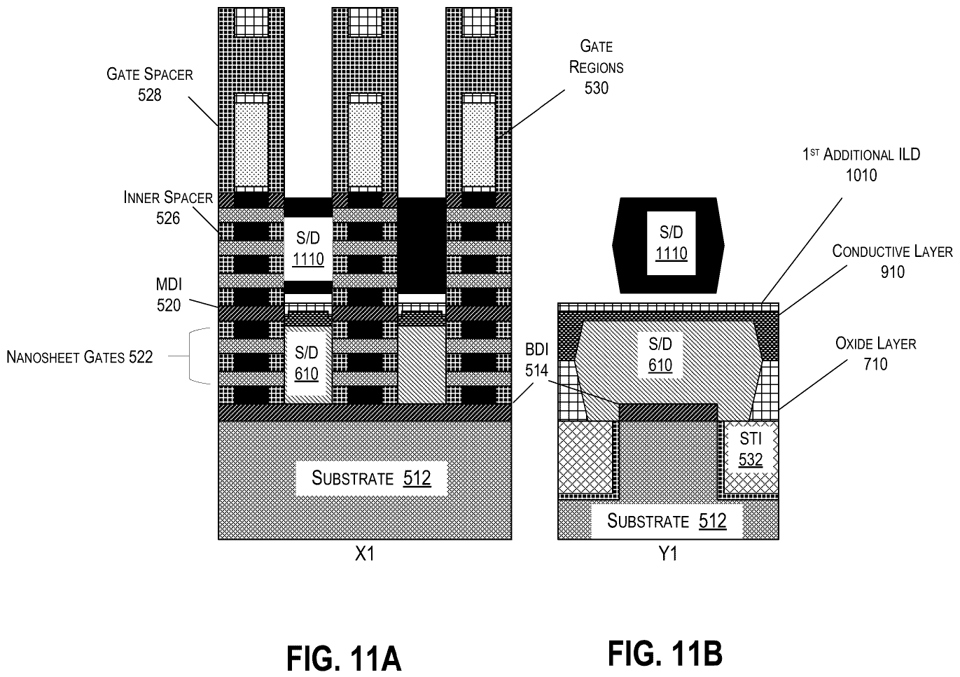

FIGS. 11A-11B illustrate side-views of a semiconductor device after the formation of the top source/drain region, in accordance with some embodiments. In an embodiment, the top source/drain region 1110 is formed by epitaxial growth over the first additional layer of ILD 1010. The top source/drain region 1110 can be formed by a low-temperature process which is compatible with the semiconductor device/conductive layer interface. As a non-limiting example, the top source/drain region 1110 can be formed a deposition of aSi and recrystallization.

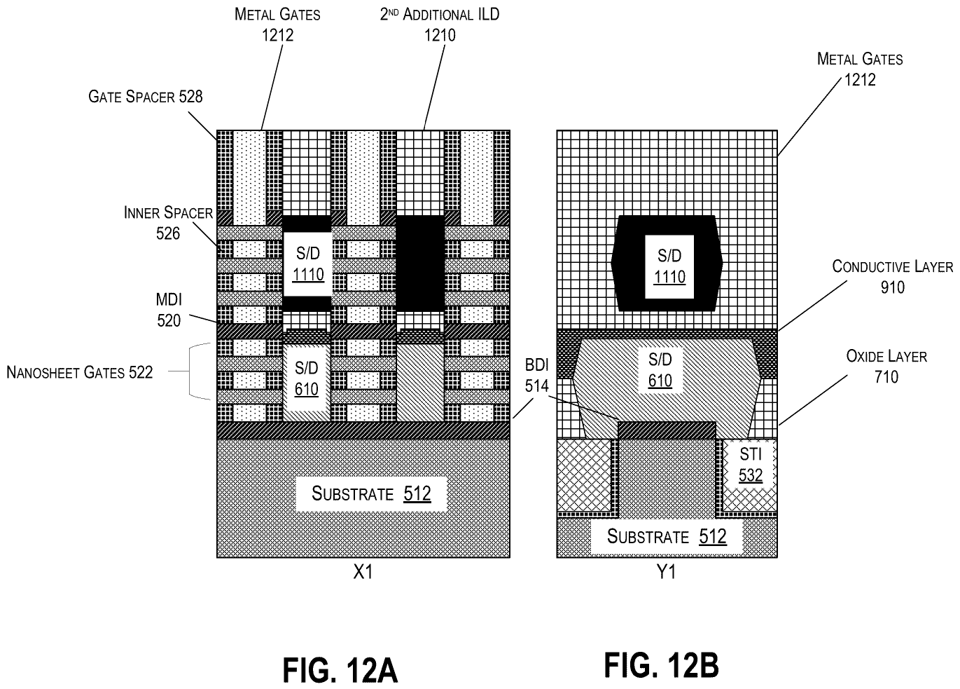

FIGS. 12A-12BI illustrate side-views of a semiconductor device after the formation of a second additional layer of ILD, in accordance with some embodiments. In an embodiment, a second additional lay ILD 1210 is deposited over the conductive layer 910 and the top source/drain region 1110. In some embodiments, a replacement gate process (RMG) is performed which can involve the replacement of the layers of SiGe with a high-k metal material, which can offer improved electrical performance and scalability. The metal gates 1212 can provide electrostatic control of the channel region. In some embodiments, the metal gates can further provide improved control over the work function, enable matching of threshold voltages, and reduce semiconductor device variability.

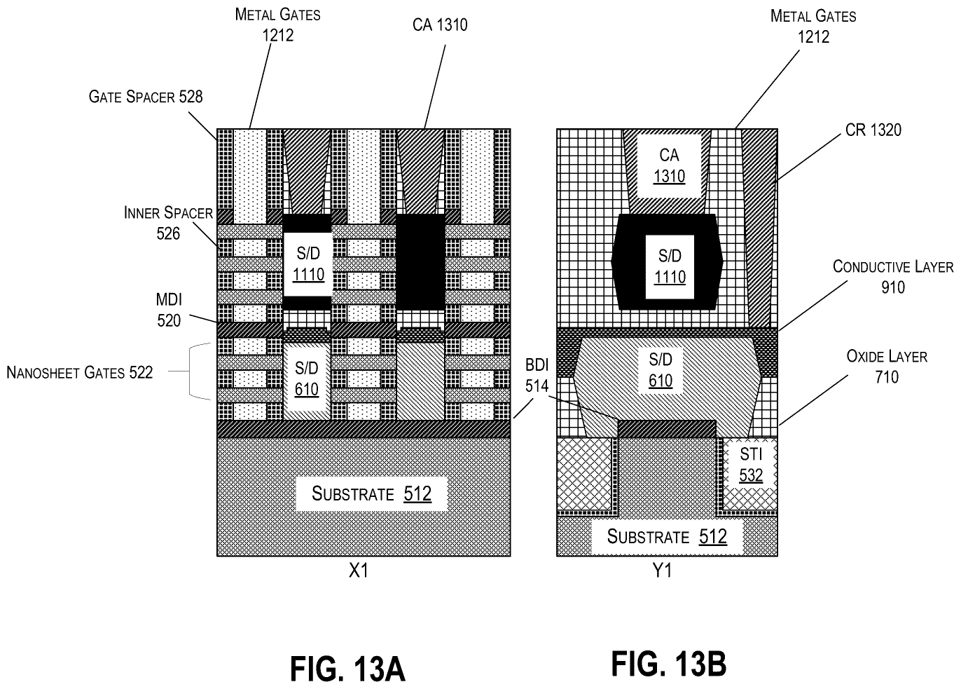

FIGS. 13A-13B illustrate side-views of a semiconductor device after the middle of line (MOL) processes, in accordance with some embodiments. In an embodiment, the formation of the MOL involves the formation of the metal layers and interconnects that connect various components and transistors on the semiconductor device. In several embodiments, during the MOL process, multiple metal layers are deposited and patterned on the semiconductor device. These metal layers serve as electrical connections, such as the top contact CA 1310, and the bottom contact, CR 1320, which allow signals to pass between different parts of the integrated circuit. In addition to metal layers, insulating layers (often made of low-k dielectric materials, such as ILD) can be deposited between metal layers to isolate them from each other and prevent electrical interference. In some embodiments, advanced lithography and patterning techniques are used to define the intricate patterns of metal lines and vias (vertical connections between metal layers) during the MOL process.

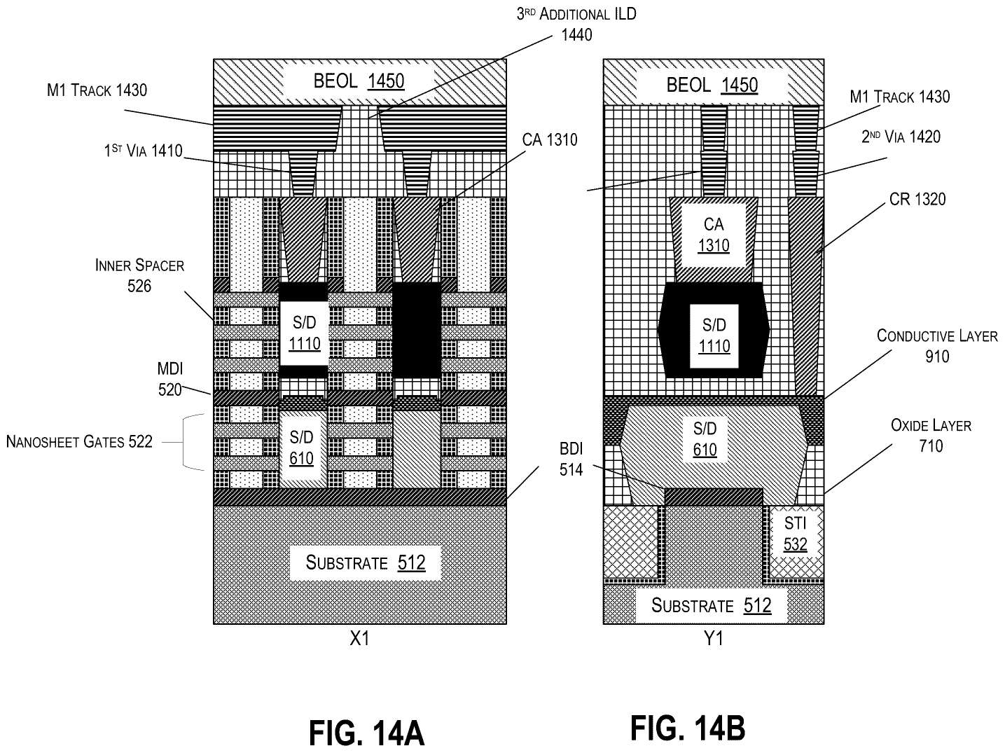

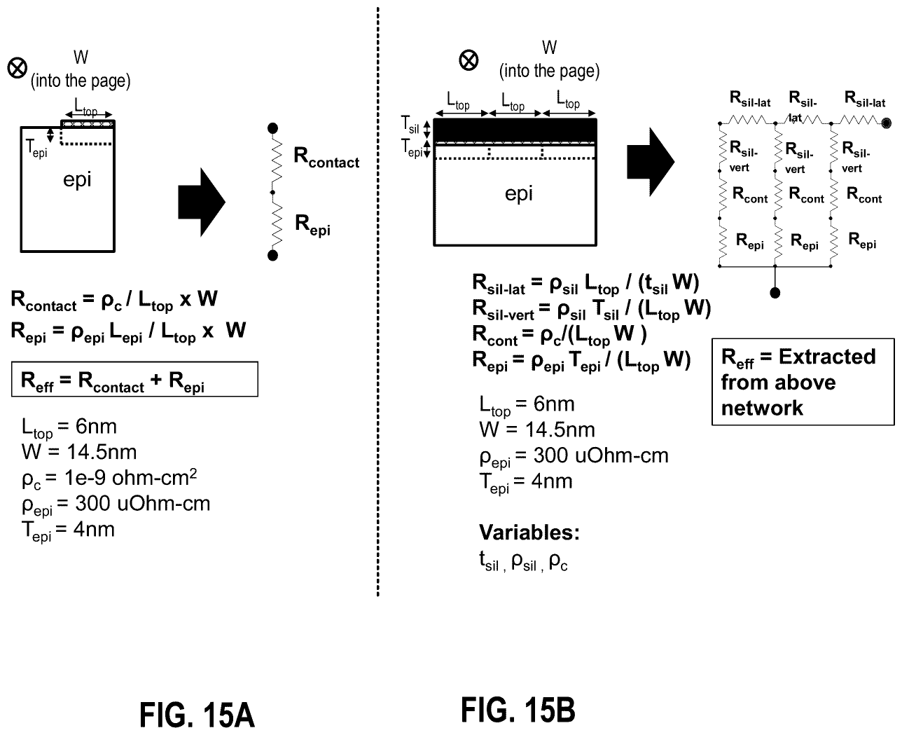

FIGS. 14A-14B illustrate side-views of a semiconductor device after the formation of the interconnects, in accordance with some embodiments. In some embodiments, the first via 1410, the second via 1420, and the M1 tracks 1430 are formed over the semiconductor device. A third additional ILD 1440 is formed to fill portions of the semiconductor device that are covered by the first via 1410, the second via 1420 and the ml tracks 1430. Subsequently, the BEOL 1450 is formed over the semiconductor device to provide the electrical connections with other devices. FIGS. 15A-15B illustrate how the contact resistivity changes in a conventional source/drain region and a semiconductor device, in accordance with some embodiments. FIG. 15A depicts the relationship between the resistivity and the dimensions of the source/drain region in the absence of the conductive layer. FIG. 15B depicts the effect of presence of the conductive layer on the relationship between the resistivity and the dimensions of the source/drain region and the dimensions of the conductive layer.

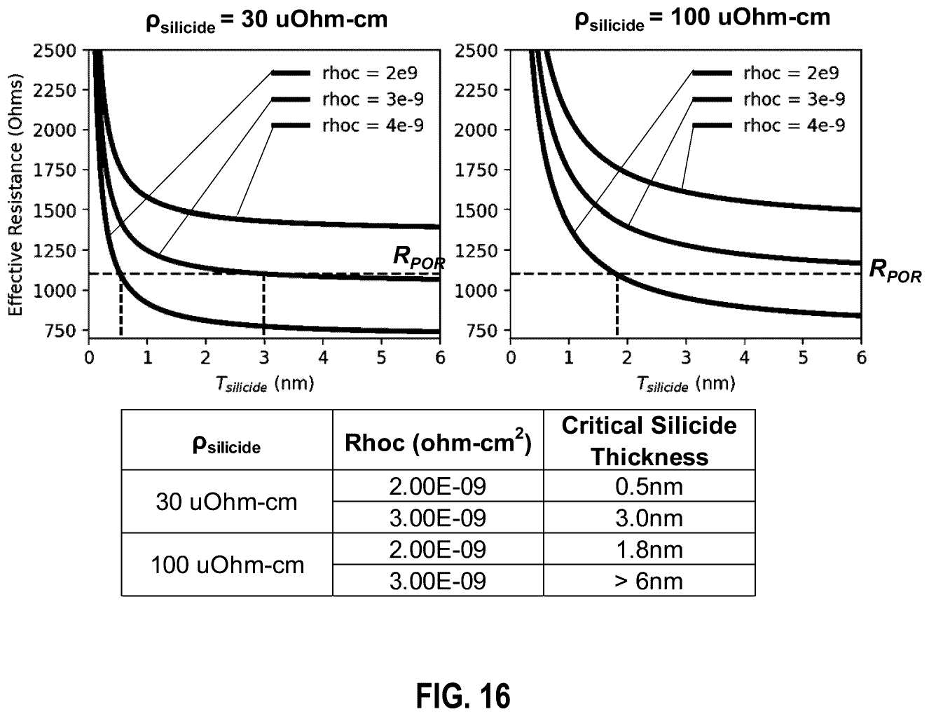

FIG. 16 illustrates a contact resistivity estimation based on a thickness of the conductive layer, in accordance with some embodiments. In some embodiments, the thickness of the conductive layer, i.e., the silicide metal layer, is changed from 0.5 nanometer to above 6 nanometers. As a result, the contact resistivity changes from 2e-9 to about 3e-9.

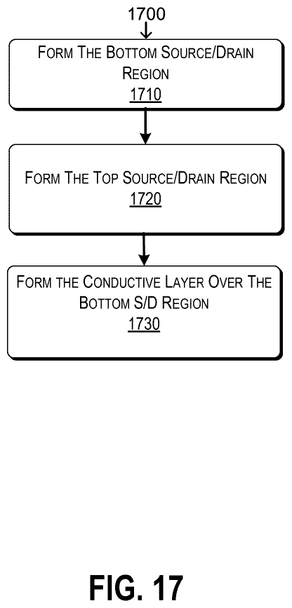

FIG. 17 illustrates block diagrams of a method 1700 for forming the semiconductor device, in accordance with some embodiments. As shown by block 1710, a bottom source/drain region is formed.

As shown by block 1720, a top source/drain region is formed.

As shown by block 1730, a conductive layer is formed over a top surface and upper half of sidewalls of the bottom source/drain region. A length of the bottom source/drain region is larger than a length of the bottom source/drain region.

In one aspect, the method and structures described above may be used in the fabrication of integrated circuit chips. The resulting integrated circuit chips can be distributed by the fabricator in raw wafer form (that is, as a single wafer that has multiple unpackaged chips), as a bare die, or in a packaged form. In the latter case, the chip may be mounted in a single chip package (such as a plastic carrier, with leads that are affixed to a motherboard or other higher-level carrier) or in a multichip package (such as a ceramic carrier that has either or both surface interconnections or buried interconnections). In any case, the chip can then be integrated with other chips, discrete circuit elements, and/or other signal processing devices as part of either (a) an intermediate product, such as a motherboard, or (b) an end product. The end product can be any product that includes integrated circuit chips, ranging from low-end applications, such as toys, to advanced computer products having a display, a keyboard or other input device, and a central processor.

### CONCLUSION

The descriptions of the various embodiments of the present teachings have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

While the foregoing has described what are considered to be the best state and/or other examples, it is understood that various modifications may be made therein and that the subject matter disclosed herein may be implemented in various forms and examples, and that the teachings may be applied in numerous applications, only some of which have been described herein. It is intended by the following claims to claim any and all applications, modifications, and variations that fall within the true scope of the present teachings.

The components, steps, features, objects, benefits, and advantages that have been discussed herein are merely illustrative. None of them, nor the discussions relating to them, are intended to limit the scope of protection. While various advantages have been discussed herein, it will be understood that not all embodiments necessarily include all advantages. Unless otherwise stated, all measurements, values, ratings, positions, magnitudes, sizes, and other specifications that are set forth in this specification, including in the claims that follow, are approximate, not exact. They are intended to have a reasonable range that is consistent with the functions to which they relate and with what is customary in the art to which they pertain.

Numerous other embodiments are also contemplated. These include embodiments that have fewer, additional, and/or different components, steps, features, objects, benefits and advantages. These also include embodiments in which the components and/or steps are arranged and/or ordered differently.

While the foregoing has been described in conjunction with exemplary embodiments, it is understood that the term “exemplary” is merely meant as an example, rather than the best or optimal. Except as stated immediately above, nothing that has been stated or illustrated is intended or should be interpreted to cause a dedication of any component, step, feature, object, benefit, advantage, or equivalent to the public, regardless of whether it is or is not recited in the claims.

It will be understood that the terms and expressions used herein have the ordinary meaning as is accorded to such terms and expressions with respect to their corresponding respective areas of inquiry and study except where specific meanings have otherwise been set forth herein. Relational terms such as first and second and the like may be used solely to distinguish one entity or action from another without necessarily requiring or implying any actual relationship or order between such entities or actions. The terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus. An element proceeded by “a” or “an” does not, without further constraints, preclude the existence of additional identical elements in the process, method, article, or apparatus that comprises the element.

The Abstract of the Disclosure is provided to allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in various embodiments for the purpose of streamlining the disclosure. This method of disclosure is not to be interpreted as reflecting an intention that the claimed embodiments have more features than are expressly recited in each claim. Rather, as the following claims reflect, the inventive subject matter lies in less than all features of a single disclosed embodiment. Thus, the following claims are hereby incorporated into the Detailed Description, with each claim standing on its own as a separately claimed subject matter.

What is claimed is:

1. A semiconductor device, comprising:
a top source/drain region;
a bottom source/drain region; and
a conductive layer over a top surface and upper half of sidewalls of the bottom source/drain region,
wherein a length of the bottom source/drain region is larger than a length of the top source/drain region.

2. The semiconductor device of claim 1, wherein the conductive layer is a metal silicide layer.

3. The semiconductor device of claim 1, further comprising:
a top contact connecting the top source/drain region to a back end of line (BEOL) through a first via and a metal line; and
a bottom contact connecting the bottom source/drain region to the BEOL through the conductive layer, a second via and the metal line.

4. The semiconductor device of claim 3, wherein the bottom contact is isolated from the top source/drain region and the top contact by a dielectric layer.

5. The semiconductor device of claim 1, further comprising:
a top transistor; and
a bottom transistor, wherein:
the top transistor includes the top source/drain region, and
the bottom transistor includes the bottom source/drain region.

6. The semiconductor device of claim 5, wherein a length of the top transistor is equal to a length of the bottom transistor.

7. The semiconductor device of claim 6, wherein the conductive layer is extended through the length of the bottom transistor.

8. The semiconductor device of claim 1, wherein a resistivity of the conductive layer is less than 3e-9 ohm·cm².

9. The semiconductor device of claim 1, wherein the conductive layer further covers bottom half of sidewalls of the bottom source/drain region.

10. The semiconductor device of claim 1, wherein the conductive layer conformally covers the top surface and the top half of sidewalls of the bottom source/drain region.

11. A method for forming a semiconductor device, the method comprising:
forming a top source/drain region;
forming a bottom source/drain region; and
forming a conductive layer over a top surface and upper half of sidewalls of the bottom source/drain region,
wherein a length of the bottom source/drain region is larger than a length of the bottom source/drain region.

12. The method of claim 11, wherein the conductive layer is a metal silicide layer.

13. The method of claim 11, further comprising:
forming a top contact connecting the top source/drain region to a back end of line (BEOL) through a first via and a metal line; and
forming a bottom contact connecting the bottom source/drain region to the BEOL through the conductive layer, a second via and the metal line.

14. The method of claim 13, further comprising isolating the bottom contact from the top source/drain region and the top contact by a dielectric layer.

15. The method of claim 11, further comprising:
forming a top transistor; and
forming a bottom transistor, wherein:
the top transistor includes the top source/drain region, and
the bottom transistor includes the bottom source/drain region.

16. The method of claim 15, further comprising: extending the conductive layer through a length of the bottom transistor.

17. The method of claim 11, further comprising covering bottom half of sidewalls of the bottom source/drain region by the conductive layer.

18. The method of claim 11, further comprising conformally covering the top surface and the top half of sidewalls of the bottom source/drain region by the conductive layer.

19. A semiconductor device, comprising:
a first source/drain region;
a conductive layer over a top surface and upper half of sidewalls of the first source/drain region; and
a first contact connecting the first source/drain region to a back end of line (BEOL) through the conductive layer, a via and a metal line.

20. The semiconductor device of claim 19, further comprising:
a second source/drain region, wherein a length of the first source/drain region is larger than a length of the second source/drain region.
